(19) United States
(12) Patent Application Publication
(10) Pub. No.: US 2006/0226473 A1
(43) Pub. Date: Oct. 12, 2006

(54) Gate electrode stack and use of a gate electrode stack

(76) Inventors: Dongping Wu, Dresden (DE); Matthias Goldbach, Dresden (DE); Ulrich Egger, Dresden (DE)

Correspondence Address: SLATER & MATSIL LLP, 17950 PRESTON ROAD, SUITE 1000, DALLAS, TX, 75252, US

(21) Appl. No.: 11/101,378

(22) Filed: Apr. 7, 2005

(51) Int. Cl. H01L 29/792

(52) U.S. Cl. 257/324

(57) ABSTRACT

A gate electrode stack is disposed on a substrate in a semiconductor device. A gate conductor includes at least one layer of polysilicon and at least one layer of poly-Si₁₋ₓ,Geₓ material. The invention is also concerned with a process. This structure can be etched effectively since an end point detection is enabled.

### TECHNICAL FIELD

This invention relates generally to a gate electrode stack and the use of the gate conductor stack.

### BACKGROUND

A gate electrode stack in a conventional DRAM device can comprise the following layers (from substrate (bottom) up):
Silicon (usually substrate material)
Gate oxide
Polysilicon (e.g. N⁺ doped or P⁺ doped)
W/WN/Ti or WSiₓ
Cap and/or encapsulation layer

The polysilicon layer and the W/WN/Ti (or other materials such as WSiₓ) layer comprise the gate conductor (GC) stack in the gate electrode stack. A thin Ti flash layer in the W/WN/Ti metal stack is used to guarantee good contact properties between the metal stack and the polysilicon layer, since Ti silicide is formed at the interface after full processing.

In principle such a gate electrode stack is described in U.S. Pat. No. 6,716,734 B2, which is incorporated herein by reference.

The etching of a GC stack is challenging since after the etching of the metal stack, an over-etch into the polysilicon layer must be performed. This over-etch is difficult to control since the end-point of the over-etch is primarily controllable only through fixed time. There is no end-point signal generated when the over-etch is performed into the polysilicon layer.

Typical etch chemistries for plasma dry-etching of a W/WN/Ti stack are Cl₂, NF₃, O₂ and HBr, which are quite aggressive chemistries, while Cl₂, O₂ and NF₃ are typically used etch chemistries for WiSiₓ etch.

### SUMMARY OF THE INVENTION

In one aspect, the invention provides a design of a gate electrode stack that is easy to produce. In another aspect, the invention provides a process for the manufacturing of a gate electrode stack. The use of a gate electrode stack is also disclosed.

Within the gate electrode stack, according to embodiments of the invention, a polysilicon layer and a poly-Si₁₋ₓGeₓ layer form a GC-stack, the relative position of the layers, i.e., which is above the other one, can vary. The introduction of the poly-Si₁₋ₓGeₓ layer has the effect that end-point detection can be achieved between the etching of the polysilicon layer and the poly-Si₁₋ₓGeₓ. The physical mechanism for end-point detection is related to the optical emission from excited molecules, which identifies directly or indirectly Ge. The poly-Si₁₋ₓGeₓ layer (x<0.8) has similar electrical and structural properties as polysilicon and is compatible with the overall processing.

Properties of poly-SiGe and utilization of poly-SiGe as a gate material can be referred to Dongping Wu's PhD thesis ‘Novel concepts for advanced CMOS: Materials, process and device architecture’ (ISRN KTH/EKT/FR-2004/3-SE and ISSN 1650-8599), which thesis is incorporated herein by reference.

Given the GC-stack according to embodiments of the invention it is possible to reduce the total thickness of the poly layers. Furthermore this improves the uniformity of the etch process.

Other features and advantages of the invention become apparent upon reading of the detailed description of the invention, and the appended claims provided below, and upon reference to the drawings.

### BRIEF DESCRIPTION OF THE DRAWINGS

For a more complete understanding of the present invention, and the advantages thereof, reference is now made to the following descriptions taken in conjunction with the accompanying drawing, in which:

FIGS. 1 to 6 show process steps in the manufacturing of a first embodiment of the invention;

FIG. 7 shows schematically a first embodiment of a GC-stack according to the invention;

FIG. 8 shows schematically a second embodiment of a GC-stack according to the invention;

FIG. 9 shows schematically a third embodiment of a GC-stack according to the invention; and

FIG. 10 shows schematically a fourth embodiment of a GC-stack according to the invention.

### DETAILED DESCRIPTION OF ILLUSTRATIVE EMBODIMENTS

In a conventional DRAM fabrication process, it is known that a W/WN/Ti/polysilicon (or WSiₓ/polysilicon) gate conductor stack is usually deposited by a physical vapor deposition (PVD) after gate oxide is grown on the silicon substrate. An insulation cap, which is usually nitride, is then deposited atop. A typical GC (gate conductor) structuring process then follows: the cap nitride layer is structured by lithography and nitride etch. The structured cap nitride layer is then served as a hard mask for the subsequent gate stack etch. The metal stack is first etched and a fixed time over-etch into polysilicon is then performed. An encapsulation liner, usually silicon nitride, is deposited and structured if W/WN/Ti metal stack is used. No encapsulation liner is necessary if the WSiₓ is used. Finally, the remaining polysilicon is etched with end-point detection on the underlying gate oxide.

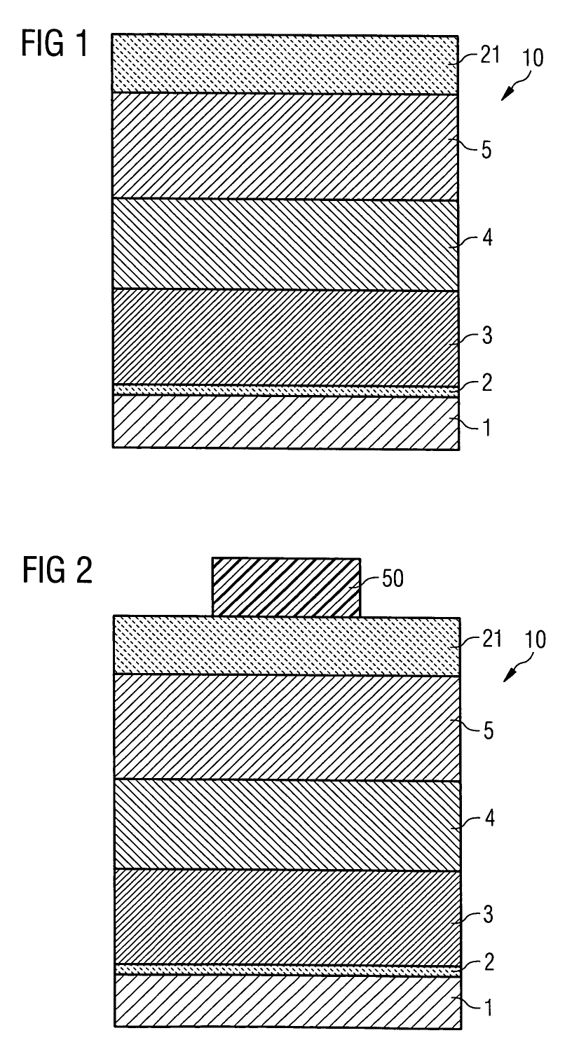

In the following FIGS. 1 to 6 the process steps for manufacturing a first embodiment of the invention are described.

FIG. 1 shows a sectional view of different layers based on a substrate. The substrate 1 is typically a silicon wafer as used, e.g., in the production of DRAM memory chips. Alternatively, this could also be a silicon chip as used in the production of logic processors especially when self-aligned source/drain contacts are needed.

The substrate is covered by a thin layer of gate dielectric 2, preferably a gate oxide.

This first embodiment will have a dual layer poly gate conductor 3, 4 within the gate electrode stack 10. Therefore, a polysilicon layer 3 is positioned on the gate oxide layer 2. The polysilicon layer 3 has thickness in the range of 3 to 100 nm, preferably 30-50 nm. On the polysilicon layer 3 a poly Si₁₋ₓGeₓ layer 4 is positioned with a thickness in the range of 3 to 100 nm, preferably 30-50 nm.

Above the Si₁₋ₓGeₓ layer 4 the metal layer W/WN/Ti (or WSiₓ) 5 is positioned. The Si₁₋ₓGeₓ layer 4 and the metal layer W/WN/Ti (or WSiₓ) 5 are covered with a cap layer 21, here made of silicon nitride.

The thickness of Ti flash layer is preferably in the range of 1 to 15 nm. The thickness of W/WN layer is in the range of 10-100 nm, preferably 30-50 nm. In principle, there is no strict limitation for the layer thicknesses in the usual range.

The next step (FIG. 2) depicts the structuring of a photo resist layer 50 using a standard lithography method. The resist layer 50 forms the mask for a dry etching of the underneath lying cap layer 21 (FIG. 3). Following this, the resist layer 50 is stripped (FIG. 4).

Now (FIG. 5) the metal stack with the metal stack layer 5 (W/WN/Ti) is etched and over-etch into poly Si₁₋ₓGeₓ layer 4 is performed, while using the cap layer 21 as hard mask. An end-point detection is obtained when the over-etch of the poly Si₁₋ₓGeₓ layer 4 is reaching the underlying poly-Si layer 3. Since the etch rate of the polysilicon layer 3 is significantly lower than that of the Si₁₋ₓGeₓ layer 4, the polysilicon layer 3 can serve as an etch stop.

FIG. 6 shows an encapsulation liner layer 20, made of silicon nitride in this case. The liner is produced by depositing silicon nitride, which is then anisotropically etched. The purpose of the encapsulation liner 20 is to prevent shorts between the W/WN/Ti stack and a bitline via, which will be manufactured later. In case WSiₓ is used, the encapsulation liner 20 can be omitted.

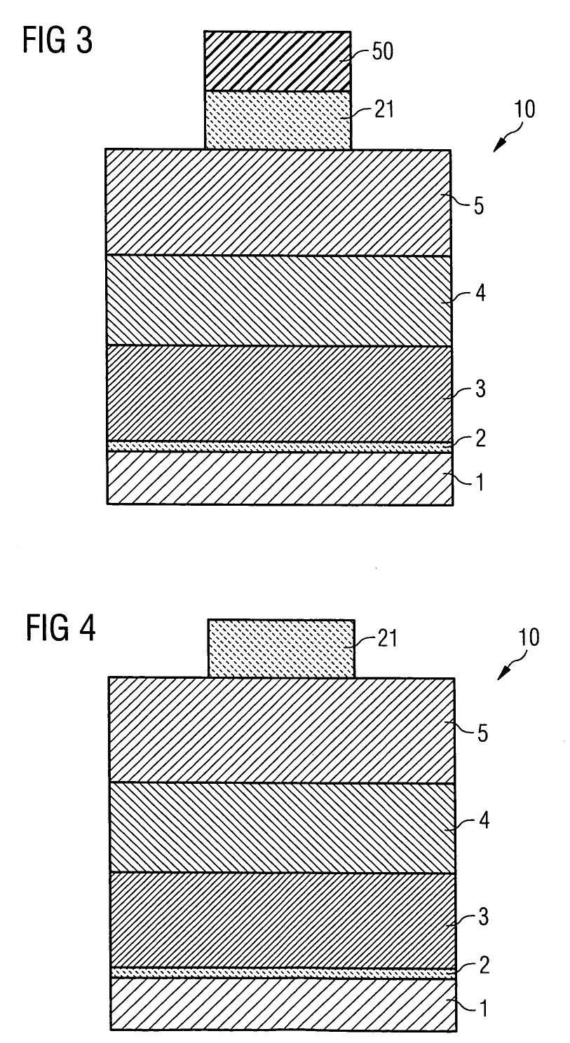

Finally a polysilicon etch is performed using the cap layer 21 as hard mask (FIG. 7). The etching is stopped on the gate oxide layer 2.

Given this first embodiment the GC etching process can detect an end-point between the Si₁₋ₓGeₓ layer 4 and the polysilicon layer 3. Due to the high etch selectivity between the Si₁₋ₓGeₓ layer 4 and the polysilicon layer 3 an effective etch stop is achieved. Consequently, an improved dry etch process window can be obtained and etch uniformity and controllability can be improved.

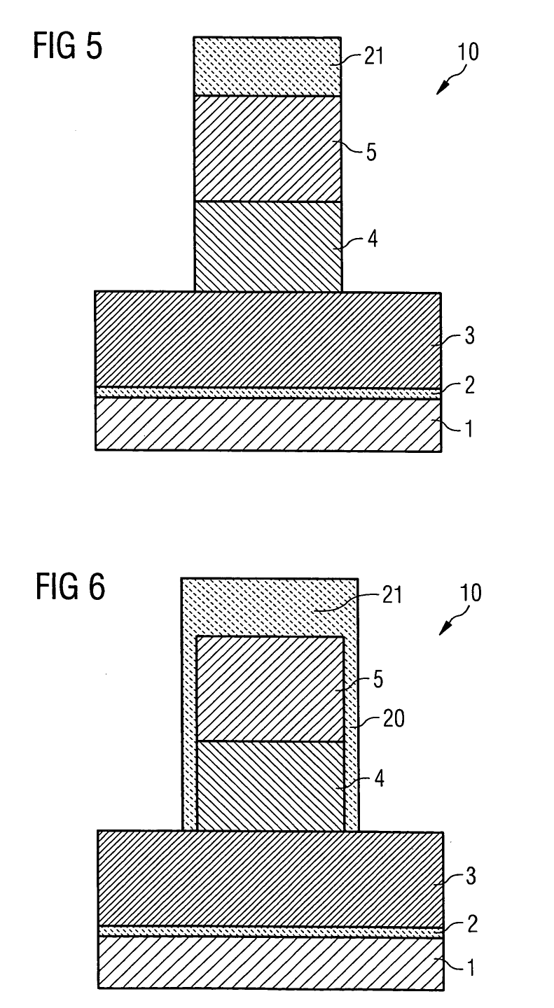

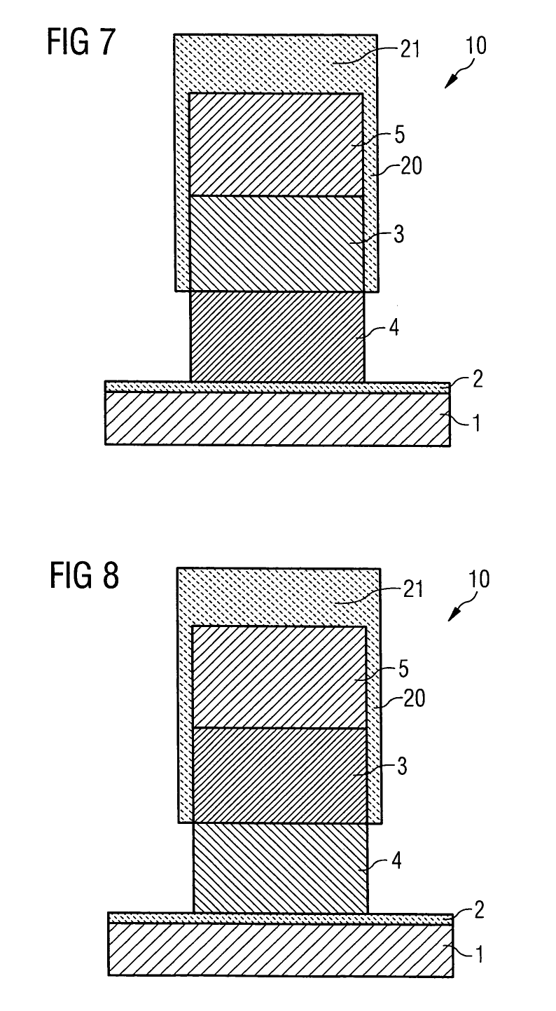

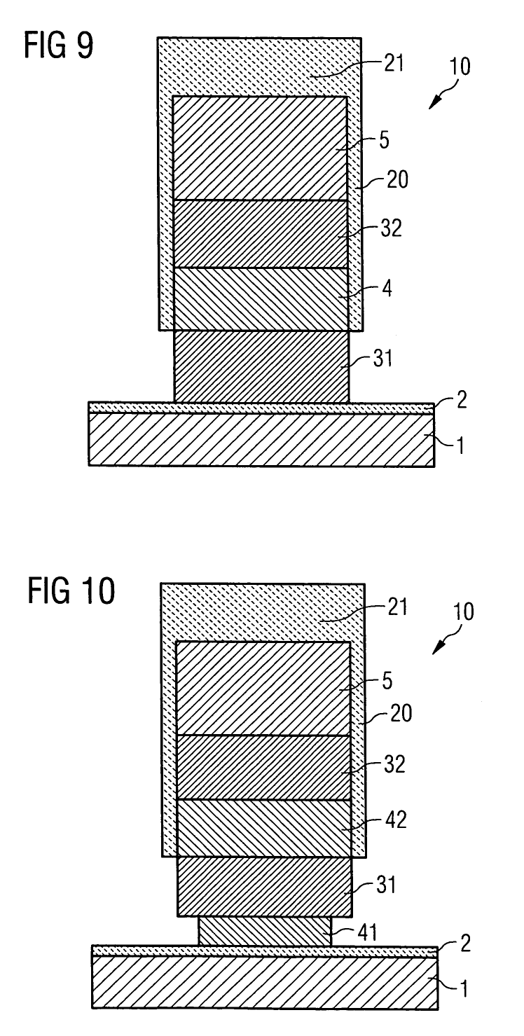

The other embodiments, depicted in FIG. 8, FIG. 9 and FIG. 10 have in principle the same structure as the first embodiment so that the above-mentioned end-point detection applies. Furthermore, the process in achieving this structure follows the same principles as discussed in connection with FIGS. 1 to 7.

FIG. 8 has an inverted poly stack and, therefore, an effective etch stop cannot be achieved, while the benefit of this embodiment is depicted in the following two paragraphs.

The difference of the second embodiment (FIG. 8) to the first embodiment is that the order of the layers in the dual layer gate conductor stack comprising the Si₁₋ₓGeₓ layer 4 and the polysilicon layer 3 is inverted. The Si₁₋ₓGeₓ layer 4 is positioned on the gate oxide layer 2 and the polysilicon layer 3 is positioned on top of the Si₁₋ₓGeₓ layer 4.

Since this embodiment has a Si₁₋ₓGeₓ layer 4/gate oxide layer 2 interface, the p-type poly gate depletion is improved. This effect is described in connection with a very specific gate dielectric in the article by Lu et al. “Improved Performance of Ultra-Thin HfO₂ CMOSFETs Using Poly-SiGe Gates”, IEEE 2002 Symposium on VLSI Technology, which article is incorporated herein by reference.

The third embodiment (FIG. 9) and fourth embodiment (FIG. 10) utilize a laminate with a triple GC stack and a quadruple GC stack respectively.

The third embodiment has a triple layer structure (from bottom up):
first polysilicon layer 31 on the gate oxide layer 2
Si₁₋ₓGeₓ layer 4 on the first polysilicon layer 31
second polysilicon layer 32 on the Si₁₋ₓGeₓ layer 4.

The thicknesses of the layers are 3-100, 3-100 and 3-100 nm, respectively.

This embodiment keeps the benefits from the first embodiment, while the interface between the poly and metal stack is still Ti/Si instead of Ti/Si₁₋ₓGeₓ as is the case in the first embodiment. This removes the possible risk due to complicated Ti−Si₁₋ₓGeₓ interaction.

The fourth embodiment depicted in FIG. 10 has a quadruple GC stack, with the following layering:
first polysilicon layer 31 on the first Si₁₋ₓGeₓ layer 41
second Si₁₋ₓGeₓ layer 42 on the first polysilicon layer 31
second polysilicon layer 32 on the second Si₁₋ₓGeₓ layer 42.

The thicknesses of the layers are 3-100, 3-100, 3-100 and 3-100 nm, respectively. (Again there is no strict limitation.)

This embodiment inherits the benefits from the second and third embodiment, while enabling the possibility to trim poly gate length. The trimming can be realized by isotropic etching of the poly Si₁₋ₓGeₓ layer 41, which is selective to the polysilicon layer 31 and the underlying gate oxide layer 2.

In general the process flow for producing the embodiments is similar to the case of metal/polysilicon gate stack, which is described earlier. The main difference lies in the metal stack over-etch into the polysilicon. Taking the first embodiment as an example: the poly-Si₁₋ₓGeₓ layer is etched during the metal stack over-etch. The end-point signal can be observed when poly-Si₁₋ₓGeₓ layer is etched away and the underlying polysilicon starts to be etched. Since the dry etch rate of polysilicon is usually much lower than that of the Si₁₋ₓGeₓ layer, the polysilicon layer can serve as an etch stop. The improvement of the gate electrode in terms of uniformity and controllability can therefore be obtained because of the capability of an end-point detection during metal over-etch into the poly layer and the etch rate difference between the poly Si₁₋ₓGeₓ and polysilicon layers.

One application for an embodiment of the invention is a dual workfunction DRAM.

What is claimed is:

1. A gate electrode stack on a substrate in a semiconductor device comprising a gate conductor with:
at least one layer of polysilicon; and
at least one layer of poly-Si₁₋ₓGeₓ material.

2. The gate electrode stack according to claim 1, further comprising at least one layer of metal gate material above the gate conductor.

3. The gate electrode stack according to claim 1, wherein the gate conductor comprises a dual layer gate conductor stack with:
one polysilicon layer; and
one poly-Si₁₋ₓGeₓ layer positioned on the polysilicon layer.

4. The gate electrode stack according to claim 1, wherein the gate conductor comprises a dual layer gate conductor stack with:
one Poly-Si₁₋ₓGeₓ layer; and
one polysilicon layer positioned on the poly-Si₁₋ₓGeₓ layer.

5. The gate electrode stack according to claim 1, wherein the gate conductor comprises a triple layer gate conductor stack with:
a first polysilicon layer;
a poly-Si₁₋ₓGeₓ layer positioned on the first polysilicon layer; and
a second polysilicon layer positioned on the poly-Si₁₋ₓGeₓ layer.

6. The gate electrode stack according to claim 1, wherein the gate conductor comprises a quadruple layer gate conductor stack with:
a first poly-Si₁₋ₓGeₓ layer;
a first polysilicon layer positioned on the first poly-Si₁₋ₓGeₓ layer;
a second poly-Si₁₋ₓGeₓ layer positioned on the polysilicon layer; and
a second polysilicon layer positioned on the second poly-Si₁₋ₓGeₓ layer.

7. The gate electrode stack according to claim 1, wherein the gate conductor includes a poly-silicon layer with a thickness greater than 1 nm.

8. The gate electrode stack according to claim 7, wherein the gate conductor includes a poly-silicon layer with a thickness greater than 3 nm.

9. The gate electrode stack according to claim 1, wherein the gate conductor comprises a poly-Si₁₋ₓGeₓ layer with a thickness greater than 3 nm.

10. The gate electrode stack according to claim 2, wherein the metal gate material comprises at least one material selected from the group consisting of W/WN/Ti and WSiₓ.

11. The gate electrode stack according to claim 1, wherein the Si₁₋ₓGeₓ x is less than 0.8 in the layer of poly-Si₁₋ₓGeₓ.

12. The gate electrode stack according to claim 1, wherein the gate conductor overlies a silicon substrate.

13. The gate electrode stack according to claim 1, further comprising at least one encapsulation liner at least partially covering the gate conductor.

14. The gate conductor stack according to claim 1, further comprising a gate oxide layer overlying the substrate, wherein the gate conductor overlies the gate oxide layer.

15. The gate conductor stack according to claim 1, wherein the gate conductor is part of a memory chip.

16. The gate conductor stack according to claim 1, wherein the memory chip comprises a DRAM chip.

17. The gate conductor stack according to claim 1, wherein the gate conductor is part of a semiconductor logic device.

18. A method for producing a semiconductor device, the method comprising:
depositing a stack that comprises at least one layer of polysilicon and at least one layer of poly-Si₁₋ₓGeₓ material;
performing a dry etching on the at least one layer of polysilicon and at least one layer of poly-Si₁₋ₓGeₓ material, wherein an over-etch into the lower lying layer of polysilicon or poly-Si₁₋ₓGeₓ material is performed, this over-etch being used as an end-point detection for the process.

19. The method according to claim 18, further comprising a metal layer over the stack.

20. The method according to claim 18, further comprising depositing a hard mask layer over the stack, wherein the dry etching is performed using the hard mask as a mask.
